(19) United States
(12) Patent Application Publication
(10) Pub. No.: US 2009/0098479 A1
(43) Pub. Date: Apr. 16, 2009

(54) EXPOSURE METHOD AND TOOL

(75) Inventors: Neil Sykes, Oxford (GB); Richard Allott, Oxford (GB)

Correspondence Address: DAVIS & BUJOLD, P.L.L.C., 112 PLEASANT STREET, CONCORD, NH, 03301, US

(73) Assignee: Exitech Limited

(21) Appl. No.: 11/814,961

(22) PCT Filed: Jan. 30, 2006
(86) PCT No.: PCT/GB06/00305

§ 371 Date: Apr. 1, 2008

(30) Foreign Application Priority Data
Jan. 28, 2005 (GB) 0501793.4

(51) Int. Cl. G03F 7/20; G03B 27/42

(52) U.S. Cl. 430/270.1; 430/323; 355/53

(57) ABSTRACT

A method for forming a regularly repeating pattern on to a substrate comprising the steps of: applying a resist on a surface of a substrate to be processed; imprinting on the applied resist a pattern formed by exposing it to a beam of ultra violet (‘UV’) light, which has been caused to pass through a suitable mask delineating the pattern and then trough a focusing lens on to the resist, so as to cause chemical changes in the resist which makes it more or less soluble in a suitable developer solution; the imprinting step being carried out: in a repetitive series of discrete exposure steps using a mask held stationery with respect to the beam and the lens that represents only a small area of the total area of the substrate and using a single short pulse of UV radiation at each step to illuminate the mask, the radiation pulse having such an energy density at the substrate that it is below the threshold value for ablation of the resist; and the series of discrete exposure steps being repeated over the full area of the surface of a substrate, to give a full structure comprising a plurality of pixels, by moving the substrate in a direction parallel to one axis of the structure to be formed on the substrate and activating the pulsed mask illumination light source at the instant that the substrate has moved over a distance equivalent to a complete number of periods of the repeating pattern on the substrate; treating the exposed resist with a developer to cause either exposed regions (for positive resists) or unexposed regions (for negative resists) to be dissolved and subsequently washed away by the developer solution to reveal the pattern formed by the remaining resist; treating the substrate with a suitable chemical etching solution, reactive plasma or abrasive particles that removes the substrate in resist free areas; and removing remaining resist from the substrate with a suitable solvent to leave a finished patterned substrate.

The invention further comprises a scanning exposure tool for carrying out the method as aforesaid.

This application is a national stage completion of PCT/GB2006/000305 filed Jan. 30, 2006 which claims priority from British Application Serial No. 0501793.4 filed Jan. 28, 2005.

### FIELD OF THE INVENTION

This invention relates to an exposure method and a tool. It is particularly concerned with the field of photo-resist exposure for the processing of large area glass substrates used in the manufacture of flat panel displays.

### BACKGROUND OF THE INVENTION

The manufacture of a flat panel display (‘FPD’) requires multiple process steps which include lithographic pattern transfer from a mask using photo-resists.

A method is known for forming a pattern on a substrate involving the steps of:

(1) applying a resist on a surface of a substrate to be processed;

(2) imprinting on the applied resist a pattern formed by exposing it to ultra violet (‘UV’) light, which has been caused to pass through a suitable mask delineating the pattern, so as to cause chemical changes in the resist which makes it more or less soluble in a suitable developer solution;

(3) treating the exposed resist with the developer to cause exposed (for positive resists) or unexposed (for negative resists) regions of the resist to be dissolved and thereafter washed away by the developer solution to reveal the pattern by the remaining resist;

(4) treating the substrate with a suitable chemical etching solution, reactive plasma or even jet of abrasive particles that removes the substrate in the resist free areas; and

(5) removing remaining resist from the substrate with a suitable solvent to leave a finished patterned substrate.

In order to form a complex electrode pattern in an indium tin oxide (‘ITO’) coating on a glass sheet for the front plate of a plasma display panel (‘PDP’) it is known to undertake the following steps.

1 A photo-resist layer (often in the form of a laminated dry film) is applied to the surface of the ITO.

2 A complex electrode pattern is imprinted into the resist by exposure through a suitable mask. The ultra violet (‘UV’) light used for this process causes chemical changes in the resist which makes it more or less soluble in a suitable developer solution.

3 The exposed substrate is treated in the developer. Exposed (for positive resists) or unexposed (for negative resists) parts of the resist are dissolved and washed away by the developer solution to leave a ‘mask’ pattern in the resist on top of the ITO surface.

4 The substrate is treated with a suitable chemical (or plasma) that dissolves the ITO from the resist free areas.

5 Finally the remaining resist layer is stripped to leave a finished patterned device.

This type of lithographic process can be repeated several times to pattern the various metallic, semi-conducting, insulating and other layers that can be used for an FPD.

Conventionally for an FPD this process is carried out using either a proximity mask or by projecting the pattern of the mask using an optical system.

### Proximity Mask Process

The mask incorporating the required pattern is held in close proximity to the resist and consequently the pattern formed in the mask has to be the same size as the image to be projected onto the resist. To ensure accurate optical transfer of the mask pattern onto the resist surface the gap between mask and resist has to be small (e.g. <0.1 mm) and held constant over the exposure area. UV light used for exposure has to be well collimated and has to be of identical intensity over the full mask area to give a uniform resist exposure dose. To allow the passage of the UV radiation (typically at a wavelength of 365 nm (i-line)) the mask has to be made of UV transmitting fused silica Such proximity exposure technology is not overly complex in terms of equipment requirements but, because of the gap and uniformity control difficulties, variations in the resist pattern can be large, leading to defects in the pattern (i.e. yield is low). Mask lifetime is also low as constant movement and handling cause rapid contamination. Nevertheless proximity exposure is at present the only mask transfer method of resist exposure available for really large FPDs such as PDPs.

### Projection Exposure Process

In this case the mask is spaced substantially from the substrate so avoiding contamination issues. Consequently an optical system has to be used to relay the image of the mask onto the resist surface. Projection exposure tools have a lens or mirror optical system between the mask and substrate to relay the image. These can be used to project a part of the full FPD pattern and operated in a step and repeat mode in order to build up a large area image at the substrate but for large FPDs it is more usual to transfer the full pattern from the mask to the substrate by means of a unity (1-times) imaging system operating in a scanning mode

In this case the mask and substrate are mounted onto the same mechanical structure and moved together. Only a small area of the mask is illuminated by UV light at any given time but by performing either a single one-dimensional scan or a repeating two dimensional raster scan of the mask and substrate together the full area of the device is exposed.

A number of companies provide scanning exposure tools for manufacturing FPDs. In all cases the magnification is unity and hence the mask has to be as large as the FPD device that must be exposed. For example Tamarak Scientific Company Inc and Anvik Corporation in the USA make one-times exposure tools for FPDs that operate in 2D raster scan mode. Tamarak usually use a high pressure mercury lamp as a source of the UV radiation often operating at 365 nm (i-line) wavelength, whereas Anvik use an excimer laser operating at 351 nm (XeF) as the UV radiation source.

To speed the exposure operation it is possible to increase the number of optical lens systems so that several work in parallel. By use of suitable parallel optics the exposure of the full device width can be accomplished with a single linear scan of mask and substrate. An example of this method of operation is the Nikon FX-51S/61S series of FPD exposure tools making use of up to seven parallel lenses. Mercury lamps are used as the source of the UV radiation.

As an alternative to multiple lenses it is possible to use a reflective optical system with a large enough field to transfer the full image width with a single linear (1-D) scan. Canon Inc manufacture an exposure tool for FPDs that uses a large (800 mm diameter) mirror as the basis of a unity (one-times) magnification large field projection imaging system. This tool can expose substrates corresponding to 32 inch FPDs on one linear scan of mask and substrate. It uses a mercury lamp as a UV source.

A characteristic common to current exposure methods exemplified by the foregoing examples is that they use masks of the same size as the device to be exposed. Such an approach is satisfactory for exposure of smaller FPDs with mask sizes up to 800×920 mm being readily available. However as FPD displays get larger e.g. 40 inch (1000 mm) and greater diagonal and especially for PDPs where sizes over 60 inch (1500 mm) and greater diagonal or more are needed the provision of suitable one-times masks is difficult and costly.

For the fabrication of integrated circuits (‘ICs’) on wafers, reduction photo resist exposure tools are used. Typically such tools have a mask that is 4- or 5-times larger than the size of the image to be projected. Hence the optical system consists of a lens with 4- or 5-times reduction. Such tools can operate in step and repeat or step and scan mode. For the later case when in the scan mode the mask has to move at a speed 4 or 5 times greater than the wafer and over a distance 4 or 5 times larger than the IC device size. The motions of the mask and wafer stages have to be very closely linked and synchronised using CNC servo systems. In almost all cases the scanning is in one dimension only, since the field of the lens is sufficient to print the design covering the full width of the IC device. The wafer is stepped between IC device locations to enable the full wafer area to be covered. Mask sizes for such tools are typically only 6×6 inches (152×152 mm) in size which means that at 4 times demagnification in scanning mode they can print IC devices up to about 35 mm long. This size is satisfactory for IC device manufacture. An example of such a tool is the ASML PAS 5500/400E which can scan IC device areas of 26×33 mm.

### SUMMARY OF THE INVENTION

According to a first aspect of the present invention there is provided a method for forming a regularly repeating pattern on to a substrate comprising the steps of:

1 applying a resist on a surface of a substrate to be processed;

2 imprinting on the applied resist a pattern formed by exposing it to a beam of ultra violet (‘UV’) light, which has been caused to pass through a suitable mask delineating the pattern and then through a focusing lens on to the resist, so as to cause chemical changes in the resist which makes it more or less soluble in a suitable developer solution; the imprinting step being carried out:
(i) in a repetitive series of discrete exposure steps using a mask held stationery with respect to the beam and the lens that represents only a small area of the total area of the substrate and using a single short pulse of UV radiation at each step to illuminate the mask, the radiation pulse having such an energy density at the substrate that it is below the threshold value for ablation of the resist; and
(ii) the series of discrete exposure steps being repeated over the full area of the surface of a substrate, to give a full structure comprising a plurality of pixels, by moving the substrate in a direction parallel to one axis of the structure to be formed on the substrate and activating the pulsed mask illumination light source at the instant that the substrate has moved over a distance equivalent to a complete number of periods of the repeating pattern on the substrate;

3 treating the exposed resist with a developer to cause either exposed regions (for positive resists) or unexposed regions (for negative resists) to be dissolved and subsequently washed away by the developer solution to reveal the pattern formed by the remaining resist;

4 treating the substrate with a suitable chemical etching solution, reactive plasma or abrasive particles that removes the substrate in resist free areas; and

5 removing remaining resist from the substrate with a suitable solvent to leave a finished patterned substrate.

According to a first preferred version of the first aspect of the present invention during the imprinting stage the size of the illuminated area at the substrate in the direction parallel to the direction in which the substrate is moving is sufficient to provide that, after passage of the substrate under the illuminated area, each part of the resist has received a sufficient number of pulses of radiation so that the combined dose of UV radiation on a given illuminated area is adequate to fully expose it.

According to a second preferred version of the first aspect of the present invention or of the first preferred version thereof the imprinting stage makes use of an optical projection system to transfer the mask pattern on to the substrate.

According to a third preferred version of the first aspect of the present invention or of any preceding preferred version thereof the mask is the same size as a small area of the full pattern on the substrate and during the imprinting stage the mask is held in close proximity to the substrate by attaching it to a puck that is caused to float on the surface of the moving substrate by means of an air flow emitted from the puck.

According to a fourth preferred version of the first aspect of the present invention or of any preceding preferred version thereof UV light source is an excimer laser.

According to a fifth preferred version of the first aspect of the present invention or of any preceding preferred version thereof wherein during the imprinting stage an edge of the area to be exposed on the substrate is defined by means of moveable blades located close to the surface of the mask.

According to a sixth preferred version of the first aspect of the present invention or of any of the preceding preferred first to fourth versions thereof wherein during the imprinting stage the substrate is exposed in a series of parallel bands and the dose of illuminating UV radiation at the regions where the bands overlap is controlled by physically shaping the two sides of the illuminating beam that are parallel to the scanning direction.

According to a seventh preferred version of the first aspect of the present invention or of any of the preceding preferred first to fourth versions thereof wherein during the imprinting stage the substrate is exposed in a series of parallel bands and the dose of illuminating UV radiation at the regions where the bands overlap is controlled by using an additional mask that has a varying transmission profile in the direction perpendicular to the substrate scanning direction.

According to a second aspect of the present invention there is provided a scanning exposure tool for carrying out the method of the first aspect or of any preceding preferred versions thereof.

According to a third aspect of the present invention there is provided a product formed by means of the method of the first aspect or of any preceding preferred versions thereof.

The present invention relates to a novel optical projection method for exposing resist to create high resolution, dense, regularly repeating structures over large area FPDs using only small masks. The optical system is generally similar to that found in semiconductor resist exposure tools in that the image is a reduced size compared to the mask but unity (1×) projection system can also be used as can enlarging projection systems if appropriate. The invention relies on the use of a pulsed light source such as a UV excimer laser, to create the resist exposing radiation. The mask remains stationary during the exposure process while the resist coated FPD substrate is moved continuously through the image plane of the projection lens.

The key to the successful implementation of this process is that the pattern to be exposed has a regular pitch in the direction in which the substrate is scanned and that the light source is activated at exactly the correct time so that the substrate moves by a distance exactly equal to (or to multiples of) the structure pitch in the time between successive exposure pulses. We call this process synchronised image scanning (SIS) as the triggering of the light source and hence the creation of the exposing image on the FPD substrate is exactly synchronised with the substrate motion so that successive images are displaced by integral numbers of pitches of the structure.

The SIS process can also be used for the direct ablation of materials when the illumination source is a high power laser and the energy density at the image plane on each laser pulse is sufficient to exceed the ablation threshold of the material. Such an SIS ablation process can be used to create deep repeating structures in materials used for FPDs and also for many other applications such as for the creation of long ink jet printer nozzles. In this disclosure we deal primarily with the process of resist exposure where the energy density is low but all the principles discussed here are appropriate for direct material ablation using higher energy densities.

Several key conditions are necessary for the SIS exposure (or ablation process) to be ffective in the creation of structures suitable for FPDs. These are listed below.

Firstly the optical mask projection system needs to have adequate resolution and field size. In general the finest structures needed in FPDs are of a few microns in size so that optical resolutions in the range of 1 to a few microns are required. Such values are readily achieved with lenses presently commonly used for laser ablation particularly in the UV region. Such lenses usually de-magnify (reduce) the mask pattern onto the FPD though 1× and enlarging lines can also be used. The combination of resolution and wavelength leads to the requirement that the lens numerical aperture (NA) usually needs to be in the range 0.05 to 0.2. Field sizes of such lenses are in the range of a few mm to over 50 mm. Such values are adequate for the SIS exposure process discussed here. The lens de-magnification factor can be any value that is convenient but bearing in mind that a pulsed light source (usually a laser) is used it is desirable to use a lens that creates a de-magnified image of the mask so that the energy density at the mask is very low. In general lens de-magnification factors in the range 1.5 times to 5 times are used but lenses that have unity (1×) magnification and even enlarging lenses can also be used if the resolution requirements are met and the energy density at the mask is sufficiently low.

Secondly it is important that the light source creating the exposing radiation is of a sufficiently short duration. This is important as the substrate to be exposed is moving continuously and the light pulse needs to be sufficiently short to ‘freeze’ its motion so that the image created is not blurred. For sheets moving at speeds up to 1 m/sec to limit the image blur to less than 1 micron requires that the pulsed source has a duration of no more than 1 micro second (10⁻⁶ sec). For this reason pulsed lasers make ideal light sources as the pulses emitted are well under 1 micro second in duration so that no image blur effects are seen even on rapidly moving substrates. UV Excimer lasers are particularly good light sources as they emit pulses at wavelengths that can readily expose common resists and have conveniently low repetition rates (a few Hz to a few kHz). This means that FPDs with structure pitches in the range of a small fraction of a mm (e.g. 50 μm) up to over 1 mm in size can be processed by this SIS exposure method at modest stage speeds. As an example a structure with a 100 μm pitch can be processed by a laser firing at 300 Hz with the firing synchronised so that the images overlap every second structure pitch with the substrate moving at only 60 mm/sec.

The third key requirement for the successful implementation of this SIS exposure process is that the laser firing has to be timed exactly with respect to the stage motion. This means that the stages need to have high resolution encoders fitted and to be highly repeatable. It also means that fast and jitter free control electronics are needed to generate the laser firing pulses from the stage encoder signals so that small changes in stage speeds (due to servo control loop delays) do not affect the exact positioning of the exposing images. Such electronics are readily available in standard CNC stage control systems (e.g. Aerotech U500 with PS0 laser firing electronics).

The fourth important condition for successful SIS exposure is that the energy density of the radiation created at the image plane by each laser pulse is below the threshold energy density needed to cause direct ablation of the resist. Since typical resists used for FPD manufacture are designed for exposure in the UV region (e.g. 351 nm) they transmit significant amounts of radiation in the UV so that the bottom of the resist layer is exposed fully. This condition suggests that the ablation threshold density is of a relatively high value (e.g. several 100 mJ/cm²). This value will decrease as the exposing wavelength is reduced as the absorption of the resist increases. Hence it is desirable to keep the exposing energy density in the region of few to 10s of mJ/cm² to avoid the possibility of resist ablation. Since the doses needed to expose the resist typically used in FPD manufacture lie in the range several 10 s to several 100 mJ/cm² it is clear that many sub-ablation threshold processes are needed to fully expose the resist by this SIS method. Typical pulse numbers may lie in the few to many 10 s range. The consequence of this is that the image size in the scanning duration needs to cover at least this number of pitches in the structure to be exposed. As an example if at least 20 pulses, each of 5 mJ/cm² are needed to fully expose a structure with 100 μm pitch then the beam width in the scanning direction must be at least 2 mm wide if successive exposing images are displaced by 1 pitch. If the images are displaced by 2 pitches, for example, the beam needs to have a width of 4 mm.

Hence the envisaged method for best using this SIS exposure process is to create an image of a stationary mask at the FPD surface which is then moved under the optical projection system to expose a band of resist across one axis of the FPD. After one band has been exposed the substrate is stepped sideways and another band adjacent to the first exposed. Clearly the sidestep distance has to be an integral number of structure pitches in the stepping direction so that the 2nd exposed band structure is exactly registered to the first band. In general the width of each band exposed should be such that when all scans are complete the full area of the FPD has been exposed. This is desirable but not essential as is discussed later.

To maximise the speed of the FPD SIS exposure process it is necessary to reduce the total number of parallel scans and to move the FPD at the highest possible speed. The former requirement is met by creating an image that is as wide as possible though this is limited by the availability of suitable lenses. The requirement to scan at the highest possible speed is met in two ways.

Firstly as pixels in FPDs are usually approximately square and consist of 3 identical sub pixels each sub pixel or cell is rectangular with an aspect ratio close to 3:1. As the SIS exposure process requires that the FPD moves by an integral number (1 or more) cells between laser pulses clearly scanning in the direction parallel to the long axis of the cells leads to a scan speed that is approximately 3 times higher than in the cell short axis direction.

Secondly it is possible to increase the scan speed by moving the FPD more than 1 cell length between exposures. Moves of 2, 3 or more can be used to increase scan speeds. The consequence of increasing the distance moved between exposing pulses is that the exposing beam at the FPD increases in size in the scan direction. As an example consider an FPD with a pixel size of 0.6×0.6 mm. Each pixel is divided into 3 cells each of 0.6×0.2 mm in size. If a laser firing at 300 Hz is used and the FPD is scanned in the cell short axis direction a scan speed of 60 mm/sec is achieved. Scanning in the orthogonal direction, parallel to the cell long axis increases this by a factor of 3 to 180 mm/sec. By moving 2 cell lengths between exposure pulses the speed is increased further to 360 mm/sec.

The requirement that each area of the FPD receives multiple pulses means that the size of the beam in the scan direction is given by the product of the cell length, the cell number moved between pulses and the number of exposing pulses required by each area. For the example above with a 0.6 mm cell length and a movement of 2 cell lengths between pulses if 20 pulses are required to achieve the correct dose in the resist then the beam size in the scan direction is 24 mm. Hence beam shapes used in this SIS exposure process are very often close to square though this is not essential.

When exposing resist in scanned bands great care has to be taken to ensure that no dose discontinuities exist at the boundary between bands. Variations in the UV radiation dose applied to the resist lead to variations in the line width of the residual resist left after development. Such line width variations cause unacceptable corresponding line width variations in the active device layer below the resist during the subsequent etching process. Such scan boundary line width discontinuities are sometimes referred to as ‘stitching errors’. Elimination of these dose discontinuities is achieved by correct control of the radiation pattern that illuminates the mask. This can be achieved by two methods.

In one case a stationary aperture of suitable shape is placed in the uniform UV radiation path just before the mask. This aperture defines the shape of the pattern of uniform radiation falling on the mask surface and correspondingly on the resist surface. To ensure no discontinuities occur at the boundary between scanned fields, an aperture that has sloping edges is used. The aperture is aligned so that the sloping edges correspond to the direction in which the mask (and substrate) are scanned. An example of a suitable shape is a trapezium that has its 2 sloping sides aligned along the scanning direction. Such an aperture at the mask causes a fall off in exposure dose on each side of the exposed area when a linear scan of mask and substrate is performed. Adjacent scans allow these intensity fall off regions to overlap. By careful adjustment of the width and slope of the aperture the total dose across each boundary between adjacent scan fields can be adjusted to be free of any discontinuities in dose.

U.S. Pat. No. 5,285,236 (1994) provides for the use of a regular hexagonal aperture to define a radiation pattern used to expose resist on a substrate in a large area scanning FPD exposure tool. By scanning in a direction perpendicular to two of the parallel sides of the hexagon and spacing adjacent scan bands by a distance equal to 1.5 times the side length of the hexagon a uniform dose is applied to the resist and ‘stitching errors’ are eliminated. However the present invention is not restricted to the use of a particular aperture shape and shapes such as trapezoids, squares, triangles or hexagons with irregular length sides. A key feature of any aperture is that it must be symmetrically shaped about a centre line which runs parallel to the scan direction.

The other method of ensuring continuity of dose across a scan boundary is to control the intensity of the radiation falling on the pattern mask by placing it close to a second (stationary mask) having a suitably varying transmission profile across its aperture. A suitable profile would have uniform high transmission in the centre section with side regions where the transmission falls to zero. The transmission profile and width of these side regions can have many forms but it is critical that the radiation transmission profile is symmetric about a centre line which is parallel to the scan direction. This means the profile and width on one side of the mask are identical to those on the other. It is also critical that the width of the mask pattern as defined by the distance between points where the transmission has dropped to half of the central peak value is exactly equal to the distance between scan bands (at the pattern mask).

Such varying transmission masks are often known as ‘apodizing masks’ and are well known in other optical applications. One way of making such a mask is to create a fine ‘half tone’ structure in a layer of chrome on a silica plate.

Control of the uniformity of the exposure dose right up to the 2 boundaries of the FPD device in the scan direction is an important issue. This is a potential problem with this SIS exposure process as the beam width in the scan direction is such that many structures are exposed on each laser pulse. If the triggering of the exposing laser is suddenly stopped at the boundary of the FPD there will be an area extending over the image where the dose delivered is incomplete. This band will be as wide as the image in the scan direction and the exposure dose over this distance will change from zero to the maximum value. Clearly this is highly undesirable so that a method is needed to prevent this.

The same problem exists at the sides of the FPD due to the shaped edge of the beam used in this direction to control close uniformity at the scan band boundary regions. At the outer edges of the extreme scan bands used to expose the FPD a partially exposed region with width equal to the width of the sloping structure on the ends of the beam will be created. In this region the exposure will fall from the full value to zero. Clearly this is highly undesirable so that a method is needed to control it.

Both of the edge problems described are solved by the same method, which involves the use of blades positioned close to the mask that move into the beam to obscure the radiation in the boundary regions. The blades are motor driven and controlled from the stage control system so can be driven into the beam at the correct time during the process. The blades are oriented with their flat faces parallel to the surface of the mask, and are located very close to the mask surface such that the blade edge is accurately imaged on to the substrate surface. Four blades are required in total, one to deal with each of the four substrate boundaries. In practice blades are sensibly mounted in pairs on a two axis CNC stage system and are designed so that the blade edges are exactly parallel to the FPD (and mask) structure pattern.

To solve the scan direction edge problem a blade is moved into the beam at the mask to reduce the beam width progressively as the FDP boundary is approached. This means that the motion of the blade has to be accurately synchronized in position to the motion of the main FPD stage. This is exactly the method used in standard lithographic exposure scanning tools to link the mask stage to the wafer stage so is readily implemented in the control system. The blade clearly has to move a distance and at a speed that is related to the main stage speed by the lens magnification.

The side boundary exposure control problem is solved by moving blades sideways (with respect to the scan direction) into the beam at the mask to obscure the sloping edge on the exposing beam when the extreme scan bands are exposed.

These side boundary blades are also used to control the overall width of the area exposed on the FPD surface. It is possible to set the width of each scan band such when all bands have been completed the width of the FPD device has been covered exactly. Such an arrangement maximises the process rate but is complex to set up. In practice it is preferable to work with scan bands that are a very small amount (e.g. 1 cell width) wider than the size that fits exactly into the full FPD width. In this case the beam obscuring blades used to remove the slope on each outer side of the outer scan bands are then advanced further into the beam to ‘trim’ the outer scan bands to the required width to create an FPD of exactly the correct size.

All of the above discussion has referred to the case where an optical projection system is used to transfer the pattern from a mask to the FPD. Such a method is convenient and straightforward as has been outlined.

For some FPD exposure situations however it is possible to use a proximity mask in the SIS exposure mode disclosed Such a technique is possible as the energy density on each laser pulse at the FPD is low (e.g. 5-10 mJ/cm²) so that a standard chrome on quartz mask can be used without risk of damage. A proximity mask SIS exposure process utilises a 1× mask of modest size (e.g. less than 50×50 mm). This mask is held stationary at a small distance (e.g. 50 μm) above the FPD surface and illuminated with UV radiation from a pulsed radiation source. The radiation source (or laser) is pulsed at the correct instants while the FPD is moved below the mask to achieve an SIS process as discussed above for the image projection case.

Clearly the most difficult aspect of this proximity mask SIS technique is that of controlling the distance between the FPD surface and the mask as the FPD is moved. This is in fact achieved rather easily by incorporating the mask into an air floating optical puck unit of the type described in Patents No PCT WO 2004/087363A1 and GB 0427104.5. Such an arrangement has been shown to be able to maintain a 50 μm gap between the resist and mask to typically 10 μm accuracy even over large area FPDs.

As with projection SIS exposure, for proximity SIS exposure it is also necessary to use beam shaping apertures to avoid band overlap exposure uniformity problems and moving blades to define the FPD boundaries correctly. Such devices can be incorporated into the floating optics head immediately above the mask without significant difficulty. It is also possible to combine the functions of the pattern forming mask and the beam shaping mask onto a single mask device if appropriate. Such an arrangement leads to a simpler construction within the floating optics head.

Illumination of the proximity mask must be performed with some care to avoid loss of resolution. If the gap between mask and resist is maintained at about 50 μm to 100 μm it is necessary that the illuminating radiation is collimated to within a range of angles less than 10 milliradians to avoid significant loss of resolution. It is also necessary to ensure that the illumination is uniform across the mask in the direction perpendicular to the scan direction to ensure uniformity of exposure across the scan bands. Illumination uniformity in the beam direction parallel to the scan direction is not critical since any non-uniformities in this direction are averaged by the scan motion.

Illumination of the mask within the correct angular range and with the required uniformity is readily achieved by the type of conventional m homogenisation systems used in other lithography tools and in laser ablation tools. A pair of cylinder lens arrays can readily form a top hat one dimensionally uniform beam with low (less than 10 milliradians) beam angles if correctly designed, having the correct aperture and by being placed at the correct distance from the mask. Beam homogenisation in the scan direction can also be applied with another pair of cylinder lens arrays if desired but this is not essential.

The UV radiation used for illuminating the mask on this SIS exposure tool can be from a range of sources. The primary requirements are that the wavelength is in the current region to expose the resist effectively and that the sources must emit pulses that are sufficiently short to avoid image blur.

Examples of possible laser sources that can be used with this invention are the following:

a) Excimer lasers operating at 248 nm, 308 nm or 351 nm

b) Solid state lasers based on Nd as the active medium with conversion of the output radiation to the UV operating at or close to 355 nm, 351 nm or 266 nm.

c) Solid state lasers based on Alexandrite as the active medium with conversion of the output radiation to the UV operating in the wavelength region around 375 nm.

d) Solid state lasers based on ruby as the active material with conversion of the output radiation to the UV operating at close to 345 nm.

e) Any other appropriate high power laser source that can generate radiation in the wavelength region between 200 nm and 400 nm.

Clearly in all cases optical systems have to be used to create a uniform radiation field at the mask to ensure a uniform exposure dose at the resist.

### BRIEF DESCRIPTION OF THE DRAWINGS

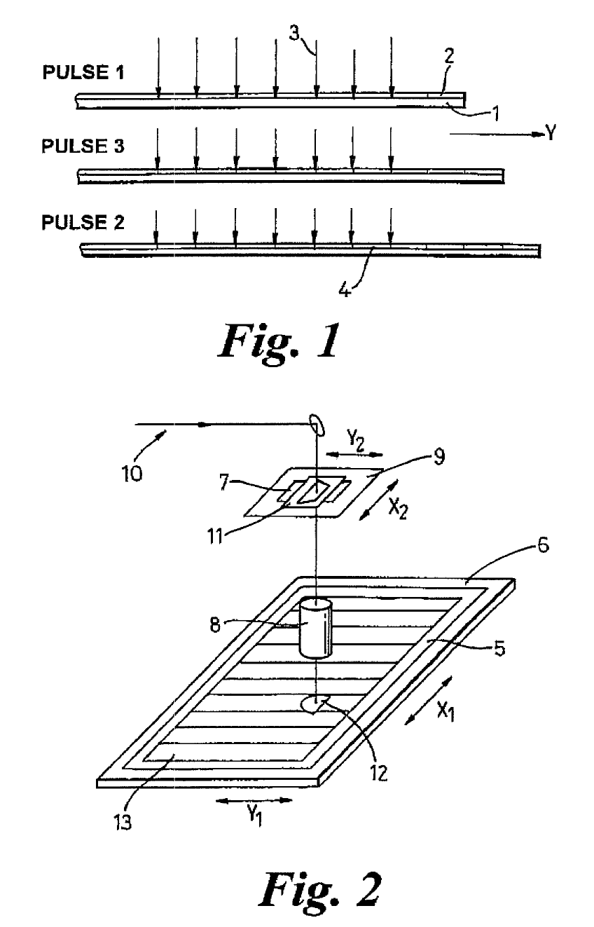

Exemplary embodiments of SIS exposure tool architectures will now be briefly discussed with reference to the accompanying diagrams; FIGS. 1, 2, 3, 4 and 5.

### DETAILED DESCRIPTION OF THE INVENTION

FIG. 1 shows the principle of the SIS exposure method. A substrate 1 coated with a photo resist layer 2 is moved progressively under the exposing pulsed radiation beam 3 in direction Y. The beam creates an image on the resist that corresponds to the required pixel or cell structure of the FPD. In the figure the image is shown to contain 6 pixel cells in the direction in which the substrate is moving. Each pulse of radiation hence exposes a band of resist that is 6 cells wide. Between laser pulses the substrate moves exactly 1 cell pitch so that the next pulse creates a pattern that exactly overlaps the first but is displaced by 1 cell pitch. In the figure shown where the beam is 6 cells wide each area of resist receives 6 pulses of radiation and then moves from the beam.

FIG. 2 shows a possible geometry for an SIS projection exposure tool. A glass substrate 5, coated with an indium-tin oxide (‘ITO’) or tin oxide (‘SnO₂’) layer and a suitable resist layer, which is to be used to form a front plate of a PDP or a glass plate coated with black matrix or other resist as used in colour filter devices in LCD displays. The plate 5 is supported on a two-axis table 6 able to move in orthogonal X, and Y, directions. The mask 7 with the pattern to be transferred is mounted in the beam above the projection lens. 8 The beam obscuring blades are supported on another two-axis table 9 able to move in orthogonal X₂ and Y₂ directions. The two directions Y₁ and Y₂ (and also X₁ and X₂) of the tables 6, 9 must be set up to be accurately parallel to each other.

A beam 10 from an excimer laser operating at 351 nm, 308 nm, 248 nm or even 193 nm is shaped and processed to create a uniform field at the mask 7. An aperture 11 above the mask defines the shape of the exposed region of the mask. This shape has sloping edges. The illuminated area 12 provided by way of the mask 7 and aperture 11 is imaged onto the resist surface on the substrate 5 using a projection lens 8 with de-magnification factor of (for example) 2.

In operation the system works as follows. The substrate is aligned rotationally and spatially using alignment cameras that are not shown in FIG. 2. The substrate is then moved to one edge and a band of resist 13 exposed by movement of the FDP in direction Y₁ Clearly as this is an edge band the sloping edge on one side of the image needs to be obscured to prevent partial exposure so that the blade with its edge parallel to the Y direction is moved into the beam by moving the blade stage the correct amount in the X direction. At the start and end of each of the Y scans the blades attached to the table 9 progressively move into the beam 10 in direction Y to obscure the beam in a controlled way to define the edge of the exposed area accurately.

After completing this scan the blade obscuring the beam slope is removed from the beam and the substrate is stepped sideways (in direction X₁) by some appropriate distance that depends on the shape of the lens field defining aperture but is less than the full width of the exposed band. Scans in Y₁ are then repeated. For the last scan the appropriate side blade needs to be moved into the beam to obscure the beam sloping edge. After complete coverage of substrate the process is completed.

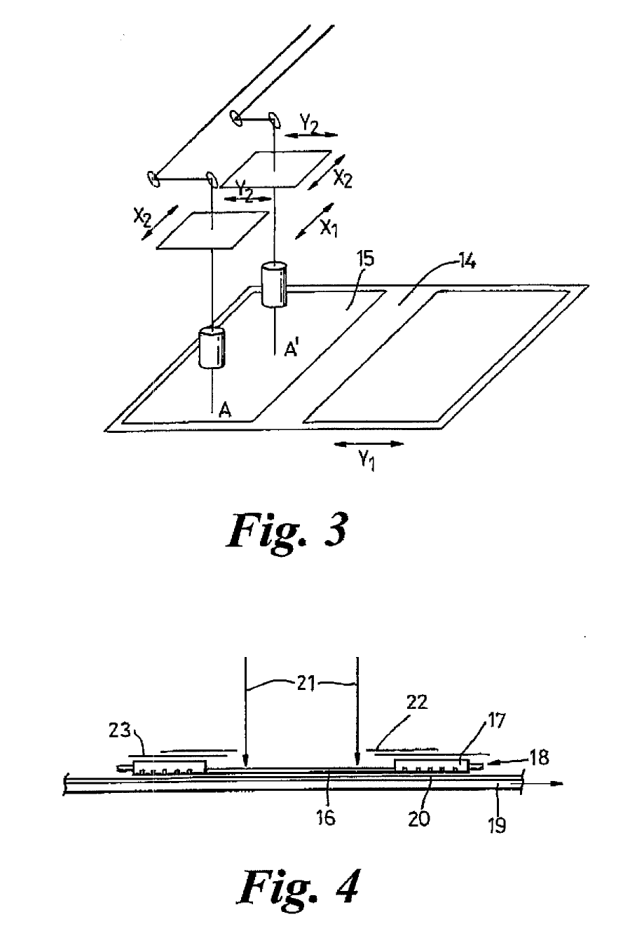

FIG. 3 shows the case where only ten scans are required to cover the full FDP area. The more likely is that the lens field will be substantially smaller which leads to the requirement for more scans. A typical lens field could be up to 50 mm in diameter. Allowing for a trapezoidal or sloping edge shape means that the side step distance may typically be only 40 mm so that up to 24 repeating scans are needed to complete the exposure of a 42″ FPD.

FIG. 4 shows another possible exposure tool arrangement. Here the substrate stages are much larger so that glass sheets 14 with multiple FPDs can be exposed. Because of the larger size of the substrate it is convenient to restrict the motion of this stage to one axis (Y₁). In this case the motion of beam with respect to the substrate in the X direction is achieved by mounting the mask and lens assembly on a carriage that moves on a stage in the X direction on a gantry over the substrate. Such an arrangement using split axes is convenient for large substrates as the footprint of the tool is reduced.

FIG. 3 also shows the use of two parallel identical optical projection channels creating two exposing areas (A, A′) on the FPD substrate 15 at the same time. Such an arrangement reduces the total exposure time without having to increase stage speed. In principle it is possible to have more than two parallel projection channels operating at the same time. It is currently believed that a practical limit is set by the proximity of the masks and blade stages as well as the increasing complexity of the tool.

Different tool architectures to those shown in FIGS. 2 and 3 are also feasible. For the case where the substrate is very large it is possible to maintain it stationary during exposure and have all the required motions occurring at the mask plane. In this case the mask and projection optics are carried on a carriage that can move in two axes on gantries over the top of the substrate.

An alternative arrangement is to operate with the substrate held in the vertical plane. Such an arrangement could apply to both of the architectures shown in FIGS. 2 and 3 but is likely to be more easily realised for the split axis system shown in FIG. 3. In this case the (large) substrate to be exposed would be held on its edge and move horizontally in the Y1 direction while the mask stages move in the parallel Y2 direction. Movement of the exposure pattern along the length of each FPD is achieved by stepping the mask carriage vertically in the X1 direction with corresponding mask position correction by movement in the parallel X2 direction.

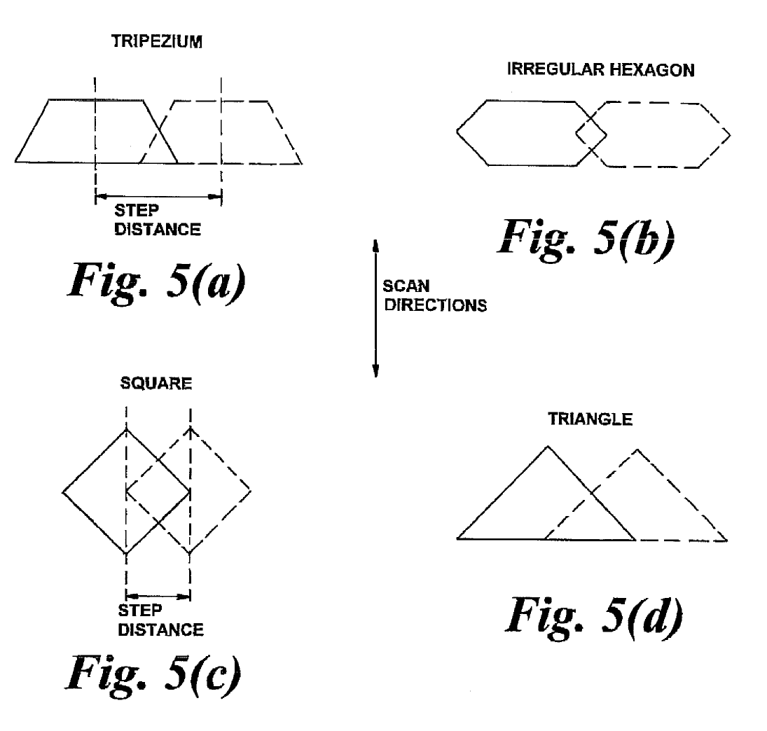

FIG. 5 shows a possible arrangement for implementing the SIS exposure process using a proximity mask. A thin chrome-on-quartz mask with a 1× pattern of the structure to be created 16 is retained at the bottom of an air puck 17 provided with an air supply 18 to allow it to float above the FPD substrate 19 coated with resist 20. The mask is mounted so that the separation between it and the resist surface is held constant and is generally in the range of a few 10s of microns to at most a few 100 microns. The puck is stationary and the substrate moves below it at the correct speed so that successive exposure pulses by the radiating beam 21 correspond to the pixel structure exactly. A beam shaping aperture 22 and 2 axis blade stage assembly 23 are placed as close as possible to the mask surface.

FIG. 5 shows some of the possible apertures

(a) trapezium

(b) irregular hexagon

(c) square, and

(d) triangle

that can be positioned before a mask to define the shape of the lens exposure field and to control the overlap of adjacent scan regions to avoid stitching effects due to dose variations. The step distance between exposure bands is set by the requirement for the overlap to occur at the point where the dose is half the maximum. In a scanning situation this corresponds to the position in the aperture where the height at the edge is half the full aperture height. This means that for square or triangular apertures the step distance is only half the aperture diagonal which leads to a requirement for multiple scans to cover the full FPD area. For trapezoidal or hexagonal apertures on the other hand the step distance can be a much larger fraction of the lens exposure field as shown in the figure. Such an arrangement leads to a substantially reduced number of scans to cover the full FPD area.

1.-10. (canceled)

11. A method for forming a regularly repeating pattern on to a substrate, the method comprising the steps of:
a) applying a resist on a surface of a substrate to be processed;
b) imprinting on the applied resist a pattern formed by exposing thr resist to a beam of ultra violet (‘UV’) light, which has been caused to pass through a suitable mask delineating the pattern and then through a focussing lens on to the resist, so as to cause chemical changes in the resist which makes the resist more or less soluble in a suitable developer solution; and the imprinting step being carried out:
(i) in a repetitive series of discrete exposure steps, using a mask held stationery with respect to the beam and the lens that represents only a small area of the total area of the substrate and using a single short pulse of UV radiation at each step to illuminate the mask, the radiation pulse having such an energy density at the substrate that is below the threshold value for ablation of the resist; and
(ii) the series of discrete exposure steps being repeated over the full area of the surface of a substrate to give a full structure comprising a plurality of pixels, by moving the substrate in a direction parallel to one axis of the structure to be formed on the substrate and activating the pulsed mask illumination light source at the instant that the substrate has moved over a distance equivalent to a complete number of periods of the repeating pattern on the substrate;
c) treating the exposed resist with a developer to cause either exposed regions (for positive resists) or unexposed regions (for negative resists) to be dissolved and subsequently washed away by the developer solution to reveal the pattern formed by the remaining resist;
d) treating the substrate with one of a suitable chemical etching solution, reactive plasma and abrasive particles that removes the substrate in resist free areas; and
e) removing remaining resist from the substrate with a suitable solvent to leave a finished patterned substrate.

12. The method as claimed in claim 11, further comprising the step of, during the imprinting stage, of sufficiently sizing the illuminated area at the substrate in a direction parallel to the direction in which the substrate is moving so that, after passage of the substrate under the illuminated area, each part of the resist has received a sufficient number of pulses of radiation so that a combined dose of UV radiation on a given illuminated area is adequate to fully expose the resist.

13. The method as claimed in claim 11, further comprising the step of, during the imprinting stage, using an optical projection system to transfer the mask pattern on to the substrate.

14. The method as claimed in claim 11, further comprising the step of sizing the mask a same size as a small area of the full pattern on the substrate and, during the imprinting stage, holding the mask in close proximity to the substrate by attaching the mask to a puck that is caused to float on the surface of the moving substrate by air flow emitted from the puck.

15. The method as claimed in claim 11, further comprising the step of using an excimer laser as the UV light source.

16. The method as claimed in claim 11, further comprising the step of, during the imprinting stage, defining an edge of the area to be exposed on the substrate by moveable blades located close to the surface of the mask.

17. The method as claimed in claim 11, further comprising the step of during the imprinting stage, exposing the substrate in a series of parallel bands and controlling the dose of illuminating UV radiation, at the regions where the bands overlap, by physically shaping two sides of the illuminating beam that are parallel to the scanning direction.

18. The method as claimed in claim 11, further comprising the step of, during the imprinting stage, exposing the substrate in a series of parallel bands and controlling the dose of illuminating UV radiation at the regions where the bands overlap by using an additional mask that has a varying transmission profile in the direction perpendicular to the substrate scanning direction.

19. A scanning exposure tool for carrying out a method for forming a regularly repeating pattern on to a substrate, in which the method comprises the steps of:
a) applying a resist on a surface of a substrate to be processed;
b) imprinting on the applied resist a pattern formed by exposing thr resist to a beam of ultra violet (‘UV’) light, which has been caused to pass through a suitable mask delineating the pattern and then through a focussing lens on to the resist, so as to cause chemical changes in the resist which makes the resist more or less soluble in a suitable developer solution; and the imprinting step being carried out:
(i) in a repetitive series of discrete exposure steps, using a mask held stationery with respect to the beam and the lens that represents only a small area of the total area of the substrate and using a single short pulse of UV radiation at each step to illuminate the mask, the radiation pulse having such an energy density at the substrate that is below the threshold value for ablation of the resist; and
(ii) the series of discrete exposure steps being repeated over the full area of the surface of a substrate to give a full structure comprising a plurality of pixels, by moving the substrate in a direction parallel to one axis of the structure to be formed on the substrate and activating the pulsed mask illumination light source at the instant that the substrate has moved over a distance equivalent to a complete number of periods of the repeating pattern on the substrate;
c) treating the exposed resist with a developer to cause either exposed regions (for positive resists) or unexposed regions (for negative resists) to be dissolved and subsequently washed away by the developer solution to reveal the pattern formed by the remaining resist;
d) treating the substrate with one of a suitable chemical etching solution, reactive plasma and abrasive particles that removes the substrate in resist free areas; and
e) removing remaining resist from the substrate with a suitable solvent to leave a finished patterned substrate.

20. A product formed by a method for forming a regularly repeating pattern on to a substrate, in which the method comprises the steps of:
a) applying a resist on a surface of a substrate to be processed;
b) imprinting on the applied resist a pattern formed by exposing thr resist to a beam of ultra violet (‘UV’) light, which has been caused to pass through a suitable mask delineating the pattern and then through a focussing lens on to the resist, so as to cause chemical changes in the resist which makes the resist more or less soluble in a suitable developer solution; and the imprinting step being carried out:
(i) in a repetitive series of discrete exposure steps, using a mask held stationery with respect to the beam and the lens that represents only a small area of the total area of the substrate and using a single short pulse of UV radiation at each step to illuminate the mask, the radiation pulse having such an energy density at the substrate that is below the threshold value for ablation of the resist; and
(ii) the series of discrete exposure steps being repeated over the full area of the surface of a substrate to give a full structure comprising a plurality of pixels, by moving the substrate in a direction parallel to one axis of the structure to be formed on the substrate and activating the pulsed mask illumination light source at the instant that the substrate has moved over a distance equivalent to a complete number of periods of the repeating pattern on the substrate;
c) treating the exposed resist with a developer to cause either exposed regions (for positive resists) or unexposed regions (for negative resists) to be dissolved and subsequently washed away by the developer solution to reveal the pattern formed by the remaining resist;
d) treating the substrate with one of a suitable chemical etching solution, reactive plasma and abrasive particles that removes the substrate in resist free areas; and
e) removing remaining resist from the substrate with a suitable solvent to leave a finished patterned substrate, means of a method as claimed in claim 11.
